(19) United States
(12) Patent Application Publication
(10) Pub. No.: US 2012/0074529 A1
(43) Pub. Date: Mar. 29, 2012

(54) SEMICONDUCTOR PACKAGE WITH THROUGH ELECTRODES AND METHOD FOR MANUFACTURING THE SAME

(75) Inventors: Ki-Young KIM, Seongnam-si (KR); Myung-Geun PARK, Seoul (KR); Jin-Ho BAE, Icheon-si (KR)

(73) Assignee: HYNIX SEMICONDUCTOR INC., Icheon-si (KR)

(21) Appl. No.: 12/981,112

(22) Filed: Dec. 29, 2010

(30) Foreign Application Priority Data
Sep. 27, 2010 (KR) 10-2010-0093223

(51) Int. Cl. H01L 29/41; H01L 21/58

(52) U.S. Cl. 257/621; 438/107; 257/E29.112; 257/E21.505

(57) ABSTRACT

A semiconductor package may include a substrate with a first surface over which bond fingers are formed. At least two semiconductor chips may be stacked on the first surface of the substrate and each chip may have via holes. The semiconductor chips may be stacked such that the respective via holes expose the respective bond fingers of the substrate. Through electrodes may be formed in the via holes. The through electrodes may comprise carbon nanotubes grown from the exposed bond fingers of the substrate, where the through electrodes may be electrically connected with the semiconductor chips.

### CROSS-REFERENCE TO RELATED APPLICATIONS

The present application claims priority to Korean patent application number 10-2010-0093223 filed on Sep. 27, 2010, which is incorporated herein by reference in its entirety.

### BACKGROUND OF THE INVENTION

The present invention relates to semiconductors, and more particularly, to a semiconductor package with through electrodes and a method for manufacturing the same.

In the semiconductor industry, packaging technologies for semiconductor integrated circuits (ICs or chips) have been developed continuously to meet the demands toward miniaturization and mounting efficiency. Recently, various techniques for stacking semiconductor chips have been developed.

The term “stack” referred to in the semiconductor industry means a technology of vertically placing together at least two semiconductor chips or semiconductor packages. By using stack technology, it is possible to realize a product having a memory capacity at least two times greater for a given area, and mounting area utilization efficiency can be increased.

In a conventional stack package, since electrical signal exchange is conducted through metal wires, operation speed decreases. Also, since a number of metal wires are used, integrity of signals on the metal wires may be degraded due to crosstalk and/or capacitive coupling. Furthermore, in a conventional stack package, because additional areas are required for connection of the metal wires, the overall size of the stack package increases. Also, because gaps are required for wire-bonding of the stacked semiconductor chips, the overall thickness of the stack package increases.

In order to overcome the problems due to the metal wires, to reduce the degradation of signals in the stack package, and to enable miniaturization of the stack package, a stack package structure using through electrodes has been suggested.

Through electrodes are formed in such a manner that via holes are defined by etching respective semiconductor chips and the via holes are filled with conductive material. The stack package structure using through electrodes are realized by stacking the semiconductor chips formed with the through electrodes such that the respective semiconductor chips are electrically connected with one another by the through electrodes.

However, in the conventional art mentioned above, a number of equipments, such as an etching equipment for defining the via holes in the semiconductor chips and a plating equipment for filling the conductive material in the via holes, are needed. Thus, in the conventional art mentioned above, a number of equipments are needed to form the through electrodes in the semiconductor chips and different processes need to be conducted in the respective equipments. Additionally, if any of the processes is not properly conducted, the manufacturing yield of the semiconductor package decreases.

Moreover, in the conventional art mentioned above, solders or other connection members are used between the through electrodes of the stacked semiconductor chips so as to electrically connect the through electrodes of the plurality of stacked semiconductor chips. Accordingly, it can be seen that the various processes may take additional time and lend complexity when manufacturing semiconductor packages.

### BRIEF SUMMARY OF THE INVENTION

Embodiments of the present invention are directed to a semiconductor package using through electrodes, and a method for manufacturing the same.

Also, embodiments of the present invention are directed to a semiconductor package which can help improve reliability and a method for manufacturing the same.

In one embodiment of the present invention, a semiconductor package includes: a substrate having a first surface over which bond fingers are formed; at least two semiconductor chips stacked over the first surface of the substrate, each semiconductor chip having via holes, the semiconductor chips being stacked such that the via holes expose the respective bond fingers of the substrate; and through electrodes, formed in the via holes with carbon nanotubes grown from the exposed bond fingers of the substrate, electrically connected with the semiconductor chips.

The bond fingers comprises at least one of Co, Mo, and Fe.

The semiconductor package may further include a catalytic metal layer formed over the bond fingers.

The catalytic metal layer comprises at least one of Co, Mo, and Fe.

The semiconductor package may further include an insulation layer formed on inner surfaces of the via holes.

The semiconductor package may further include adhesives interposed between a lowermost semiconductor chip and the first surface of the substrate and between the semiconductor chips.

The semiconductor package may further include an additional catalytic metal layer formed over an uppermost semiconductor chip; at least two additional semiconductor chips stacked over the uppermost semiconductor chip and each semiconductor chip having additional via holes, the additional semiconductor chips being stacked such that the additional via holes expose the respective additional catalytic metal layer; and additional through electrodes, formed in the additional via holes with carbon nanotubes grown from the exposed additional catalytic metal layer, electrically connected with the additional semiconductor chips.

The semiconductor package may further include redistribution lines formed over the uppermost semiconductor chip to electrically connect the through electrodes of the uppermost semiconductor chip with the additional catalytic metal layer.

In another embodiment of the present invention, a method for manufacturing a semiconductor package includes: stacking at least two semiconductor chips, each semiconductor chip having via holes, over a first surface of a substrate over which bond fingers are formed, such that the respective via holes expose the respective bond fingers of the substrate; and forming through electrodes by growing carbon nanotubes, in the via holes, from the exposed bond fingers of the substrate, wherein the through electrodes are electrically connected with the semiconductor chips.

The bond fingers may comprise at least one of Co, Mo, and Fe.

Before stacking the semiconductor chips, the method may further include forming a catalytic metal layer over the bond fingers of the substrate.

The catalytic metal layer may comprise at least one of Co, Mo, and Fe.

Before stacking the semiconductor chips, the method may further include forming an insulation layer on inner surfaces of the via holes.

Stacking the semiconductor chips may be implemented such that the semiconductor chips are stacked using adhesives between adjacent semiconductor chips and between the lowermost semiconductor chip and the first side of the substrate.

The carbon nanotubes may be grown through use of PECVD.

PECVD may be conducted using plasma which is produced by a carbon-containing gas.

The carbon-containing gas may comprise at least any one of C₂H₂, CH₄, C₂H₄, C₂H₆, and CO.

After forming the through electrodes, the method may further include forming an additional catalytic metal layer over an uppermost semiconductor chip; stacking at least two additional semiconductor chips, each additional semiconductor chip having additional via holes over the uppermost semiconductor chip, such that the additional via holes expose the respective additional catalytic metal layer; and forming additional through electrodes, by growing in the additional via holes carbon nanotubes from the exposed additional catalytic metal layer, electrically connected with the additional semiconductor chips.

After forming the through electrodes and before forming the additional catalytic metal layer on the uppermost semiconductor chip, the method may further include forming redistribution lines on the uppermost semiconductor chip in such a way as to electrically connect the through electrodes of the uppermost semiconductor chip with the additional catalytic metal layer when the additional catalytic metal layer is formed.

After forming the through electrodes, the method may further include stacking at least two additional semiconductor chips, each additional semiconductor chip having additional via holes, over the uppermost semiconductor chip such that the additional via holes expose the respective through electrodes; and forming additional through electrodes, by growing in the additional via holes carbon nanotubes from the exposed through electrodes, electrically connected with the additional semiconductor chips.

### BRIEF DESCRIPTION OF THE DRAWINGS

FIG. 1 is a cross-sectional view illustrating a semiconductor package in accordance with an embodiment of the present invention.

FIGS. 2A through 2D are cross-sectional views illustrating a method for manufacturing a semiconductor package in accordance with an embodiment of the present invention.

FIG. 3 is a cross-sectional view illustrating a semiconductor package in accordance with an embodiment of the present invention.

FIGS. 4A through 4G are cross-sectional views illustrating a method for manufacturing a semiconductor package in accordance with an embodiment of the present invention.

FIG. 5 is a cross-sectional view illustrating a semiconductor package in accordance with an embodiment of the present invention.

### DESCRIPTION OF SPECIFIC EMBODIMENTS

In various embodiments of the present invention, by stacking semiconductor chips each having via holes on a substrate and growing carbon nanotubes from bond fingers or a catalytic metal layer of the substrate, through electrodes comprising carbon nanotubes are formed in the via holes in such a way as to be electrically connected with the bond fingers or the catalytic metal layer.

Accordingly, in various embodiments of the present invention, it is possible to electrically connect the stacked semiconductor chips with the substrate and one another without performing a process for filling the via holes with conductive material. Therefore, in various embodiments of the present invention, since additional equipment and processes for filling the respective via holes to form through electrodes are not needed, manufacturing time can be shortened and manufacturing cost can be reduced, whereby manufacturing processes can be simplified.

Moreover, in various embodiments of the present invention, due to the fact that the through electrodes, comprising carbon nanotubes that have excellent electrical conductivity and mechanical properties, are formed to electrically connect the semiconductor chips with one another and the substrate, the electrical characteristics and the reliability of the semiconductor package as a whole can be improved.

Furthermore, in various embodiments of the present invention, as the through electrodes comprising carbon nanotubes are formed by growing the carbon nanotubes when the plurality of semiconductor chips are stacked on the substrate, it is not necessary to form connection members for connecting the through electrodes of the semiconductor chips. Therefore, because electrical connections between the through electrodes of the semiconductor chips are stably formed, the electrical characteristics and the reliability of the semiconductor package can be effectively improved.

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

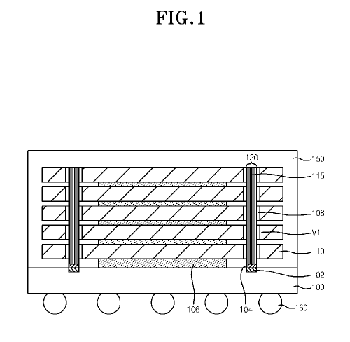

FIG. 1 is a cross-sectional view illustrating a semiconductor package in accordance with an embodiment of the present invention.

Referring to FIG. 1, bond fingers 102 are formed on a first surface of a substrate 100, and a catalytic metal layer 104 is formed on the bond fingers 102. The catalytic metal layer 104 may be formed from one or more material such as, for example, Co, Mo, or Fe.

Although not shown in a drawing, the bond fingers 102 may be used without the catalytic metal layer 104 being formed.

Accordingly, the bond fingers 102 may be formed from one or more material such as, for example, Co, Mo, or Fe.

At least two semiconductor chips 110 may be stacked on the first surface of the substrate 100, and adhesives 106 may be used to join the semiconductor chips 110 to each other and to join the bottommost semiconductor chip 110 to the substrate 100. Each of the semiconductor chips 110 has via holes V1, and an insulation layer 108 is formed on inner surfaces of the via holes V1. The semiconductor chips 110 are stacked in such a manner that the via holes V1 are aligned vertically with respect to the first surface of the substrate 100 so as to expose the bond fingers 102 or the catalytic metal layer 104 of the substrate 100.

Carbon nanotubes 115 are grown vertically with respect to the first surface of the substrate 100 from the exposed bond fingers 102 or catalytic metal layer 104. The carbon nanotubes 115 are electrically connected with the exposed bond fingers 102 or catalytic metal layer 104. Through electrodes 120, which comprise carbon nanotubes 115 and are electrically connected with the semiconductor chips 110, are formed in the via holes V1.

Accordingly, the semiconductor chips 110 are electrically connected with one another and the substrate 100 via the through electrodes 120.

An encapsulation member 150 is formed on the first surface of the substrate 100 in such a way as to seal the first surface of the substrate 100. Ball lands (not shown) are formed on a second surface of the substrate 100 which faces away from the first surface, and external connection terminals 160 are formed on the ball lands.

In the semiconductor package in accordance with an embodiment of the present invention, the through electrodes 120, which electrically connect the semiconductor chips 110 with one another and the substrate 100, comprise carbon nanotubes 115 which are grown from the bond fingers 102 or the catalytic metal layer 104 of the substrate 100. Accordingly, in an embodiment of the present invention, a semiconductor package structure may have improved electrical characteristics and reliability due to the electrical conductivity and mechanical properties of the carbon nanotubes 115.

Also, in the semiconductor package in accordance with an embodiment of the present invention, since the carbon nanotubes 115 are grown from the bond fingers 102 or the catalytic metal layer 104 of the substrate 100 to pass through the via holes V1 defined in the plurality of semiconductor chips 110, connection members for electrically connecting the through electrodes 120 of the semiconductor chips 110 may not be necessary. Accordingly, in an embodiment of the present invention, the electrical connections between the through electrodes 120 of the semiconductor chips 110 are stabilized, and the electrical characteristics and the reliability of the semiconductor package can be effectively improved.

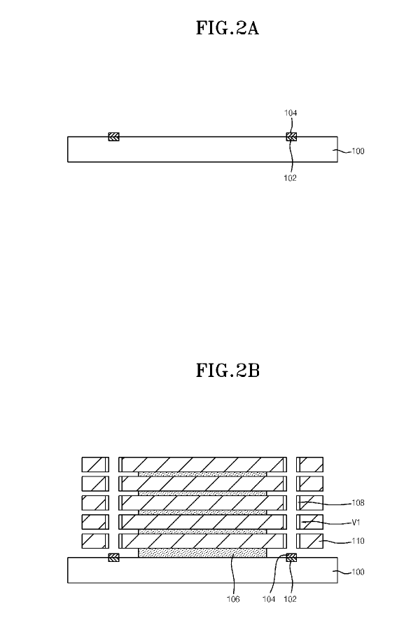

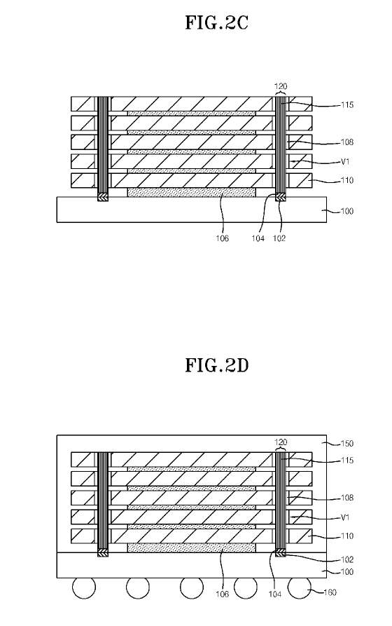

FIGS. 2A through 2D are cross-sectional views illustrating a method for manufacturing a semiconductor package in accordance with an embodiment of the present invention.

Referring to FIG. 2A, the substrate 100, having the first surface on which bond fingers 102 are formed and the second surface which faces away from the first surface on which ball lands (not shown) are formed, is prepared. A catalytic metal layer 104 is formed on the bond fingers 102. The catalytic metal layer 104 may be formed of one or more material such as, for example, Co, Mo, or Fe.

Although not shown in a drawing, the bond fingers 102 may be used without the catalytic metal layer 104 being formed. Accordingly, the bond fingers 102 may be formed from material such as, for example, Co, Mo, or Fe.

Referring to FIG. 2B, at least two semiconductor chips 110, each having via holes V1, may be stacked on the first surface of the substrate 100, and adhesives 106 may be used to join the semiconductor chips 110 to each other and to join the bottommost semiconductor chip 110 to the substrate 100. Before stacking the semiconductor chips 110, an insulation layer 108 is formed on inner surfaces of the via holes V1. The semiconductor chips 110 are stacked in such a manner that the via holes V1 are aligned vertically with respect to the first surface of the substrate 100 so as to expose the bond fingers 102 or the catalytic metal layer 104 of the substrate 100.

Referring to FIG. 2C, carbon nanotubes 115 are grown from the exposed bond fingers 102 or catalytic metal layer 104. As a consequence, through electrodes 120 are formed in the via holes V1. Accordingly, the through electrodes 120 may comprise the carbon nanotubes 115 and may be electrically connected with the exposed bond fingers 102 or catalytic metal layer 104 and the semiconductor chips 110.

The carbon nanotubes 115 are grown, for example, through PECVD (plasma enhanced chemical vapor deposition). The PECVD is conducted using plasma which is produced by, for example, a carbon-containing gas. The carbon-containing gas may be gas comprising, for example, one or more of C₂H₂, CH₄, C₂H₄, C₂H₆, and CO.

The carbon nanotubes 115 are grown vertically with respect to the first surface of the substrate 100 from the exposed bond fingers 102 or catalytic metal layer 104. As a consequence, the carbon nanotubes 115 are electrically connected with the exposed bond fingers 102 or catalytic metal layer 104. Accordingly, the semiconductor chips 110 may be electrically connected with one another and the substrate 100 by the through electrodes 120 comprising the carbon nanotubes 115.

Referring to FIG. 2D, an encapsulation member 150 is formed on the first surface of the substrate 100 on which the semiconductor chips 110 are stacked and the through electrodes 120 comprising the carbon nanotubes 115 are formed, in such a way as to seal the first surface of the substrate 100. External connection terminals 160 are formed on the ball lands (not shown) on the second surface of the substrate 100 facing away from the first surface.

Thereafter, while not shown in a drawing, by sequentially performing a series of subsequent processes as needed, the manufacture of a semiconductor package in accordance with an embodiment of the present invention may be completed.

In an embodiment of the present invention, by stacking semiconductor chips having via holes on the first surface of a substrate and growing carbon nanotubes from bond fingers or a catalytic metal layer of the substrate, through electrodes comprising the carbon nanotubes are formed in the via holes.

Accordingly, in an embodiment of the present invention, it is possible to electrically connect the stacked semiconductor chips with one another and the substrate by using the through electrodes comprising the carbon nanotubes without filling the via holes of the semiconductor chips with conductive material. Therefore, in an embodiment of the present invention, since additional equipment and processes for filling the via holes are not needed, manufacturing time can be shortened and manufacturing cost can be reduced.

Moreover, in an embodiment of the present invention, the through electrodes comprising the carbon nanotubes with excellent electrical conductivity and mechanical properties are formed to electrically connect the semiconductor chips with one another and the semiconductor chips with the substrate. Accordingly, good electrical connections may be made between the semiconductor chips and the substrate. Accordingly, the electrical characteristics and the reliability of the semiconductor package may be improved.

Furthermore, in an embodiment of the present invention, the carbon nanotubes may be grown to pass through the respective via holes of the stacked semiconductor chipsin, for example, a single process.

As a consequence, in an embodiment of the present invention, it may not be necessary to form connection members for connecting the through electrodes of the semiconductor chips. Thus, in an embodiment of the present invention, because the electrical connections between the through electrodes of the semiconductor chips are stabilized, the electrical characteristics and the reliability of the semiconductor package can be effectively improved.

It was described in an embodiment of the present invention that the manufacture of the semiconductor package is completed by growing in a single process the carbon nanotubes for electrically connecting the stacked semiconductor chips with one another and the substrate, so as to electrically connect the semiconductor chips all at once. I In an embodiment of the present invention, after the carbon nanotubes are grown, if failures occur for any through electrodes, carbon nanotubes can be additionally grown to connect portions of the semiconductor chips which are not properly connected electrically.

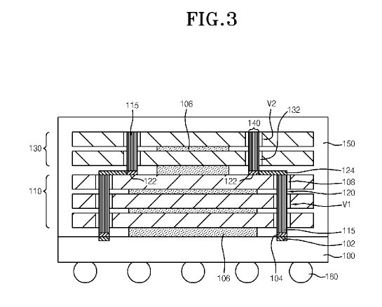

FIG. 3 is a cross-sectional view illustrating a semiconductor package in accordance with an embodiment of the present invention.

Referring to FIG. 3, bond fingers 102 are formed on a first surface of a substrate 100, and a catalytic metal layer 104 is formed on the bond fingers 102. The catalytic metal layer 104 may comprise material such as, for example, Co, Mo, or Fe. Semiconductor chips 110 may be stacked on first surface of the substrate 100, and additional semiconductor chips 130 may be stacked on top of the semiconductor chips 110.

Although not shown in a drawing, the bond fingers 102 may be used without the catalytic metal layer 104 being formed.

Accordingly, the bond fingers 102 may be formed from material such as, for example, Co, Mo, or Fe.

At least two semiconductor chips 110 may be stacked on the first surface of the substrate 100, and adhesives 106 may be used to join the semiconductor chips 110 to each other and to join the bottommost semiconductor chip 110 to the substrate 100. Each of the semiconductor chips 110 has via holes V1, and an insulation layer 108 is formed on inner surfaces of the via holes V1. The semiconductor chips 110 are stacked in such a manner that the via holes V1 are aligned vertically with respect to the first surface of the substrate 100 so as to expose the bond fingers 102 or the catalytic metal layer 104 of the substrate 100.

Through electrodes 120, which are constituted by carbon nanotubes 115 and are electrically connected with the semiconductor chips 110, are formed in the via holes V1. The carbon nanotubes 115 are grown vertically with respect to the first surface of the substrate 100 from the exposed bond fingers 102 or catalytic metal layer 104. The carbon nanotubes 115 are electrically connected with the exposed bond fingers 102 or catalytic metal layer 104 such that the semiconductor chips 110 are electrically connected with one another and the substrate 100 and the semiconductor chips 110 are electrically connected with each other.

An additional catalytic metal layer 122 is formed on portions of a top surface of the uppermost semiconductor chip 110, for example, on portions of the top surface of the uppermost semiconductor chip 110 which are adjacent to the through electrodes 120.

The additional catalytic metal layer 122 may be formed of at least one material such as, for example, Co, Mo or Fe. Redistribution lines 124 are formed on the top surface of the uppermost semiconductor chip 110 in such a way as to electrically connect the through electrodes 120 of the uppermost semiconductor chip 110 with the additional catalytic metal layer 122.

At least two additional semiconductor chips 130 are stacked on the uppermost semiconductor chip 110 using, for example, the adhesives 106. Each of the additional semiconductor chips 130 has additional via holes V2. An insulation layer 132 is formed on inner surfaces of the additional via holes V2. The additional semiconductor chips 130 are stacked in such a manner that the additional via holes V2 are aligned vertically with respect to the top surface of the uppermost semiconductor chip 110 so as to expose the additional catalytic metal layer 122 formed on the uppermost semiconductor chip 110.

Additional through electrodes 140, which may comprise carbon nanotubes 115, are formed in the additional via holes V2. The carbon nanotubes 115 are grown vertically with respect to the top surface of the uppermost semiconductor chip 110 from the exposed additional catalytic metal layer 122. The carbon nanotubes 115 are electrically connected with the exposed additional catalytic metal layer 122 such that the additional semiconductor chips 130 are electrically connected with one another, the semiconductor chips 110, and the substrate 100.

An encapsulation member 150 is formed on the first surface of the substrate 100 on which the semiconductor chips 110 and the additional semiconductor chips 130 are stacked and the through electrodes 120 and the additional through electrodes 140 comprising the carbon nanotubes 115 are formed, in such a way as to seal the first surface of the substrate 100. Ball lands (not shown) are formed on the second surface of the substrate 100 which faces away from the first surface, and external connection terminals 160 are formed on the ball lands.

In the semiconductor package in accordance with an embodiment of the present invention, the through electrodes 120 and 140, which electrically connect the semiconductor chips 110 and 130, and the substrate 100 with one another, comprise the carbon nanotubes 115. Accordingly, an embodiment of the present invention has been described where a semiconductor package structure comprises improved electrical characteristics and reliability by using the electrical conductivity and mechanical properties of the carbon nanotubes 115.

Also, in the semiconductor package in accordance with an embodiment of the present invention, since the carbon nanotubes 115 are grown to pass through the via holes V1 of the semiconductor chips 110 and the additional via holes V2 of the additional semiconductor chips 130, connection members for electrically connecting the through electrodes 120 of the semiconductor chips 110 and the additional through electrodes 140 of the additional semiconductor chips 130 are not necessary.

Accordingly, in an embodiment of the present invention, the electrical connections between the through electrodes 120 of the semiconductor chips 110 and the additional through electrodes 140 of the additional semiconductor chips 130 are stabilized, whereby the electrical characteristics and the reliability of the semiconductor package can be effectively improved.

In addition, in the semiconductor package in accordance with an embodiment of the present invention, due to the fact that the carbon nanotubes 115 are additionally grown from the additional catalytic metal layer 122 which is formed on the top surface of the uppermost semiconductor chip 110, the electrical connections between the semiconductor chips 110 and the additional semiconductor chips 130 can be stably implemented.

Therefore, in an embodiment of the present invention, even when an increased number of the semiconductor chips 110 and the additional semiconductor chips 130 are stacked on the substrate 100, stable electrical connections of the semiconductor chips 110 and the additional semiconductor chips 130 are enabled, and accordingly, the electrical characteristics and the reliability of a semiconductor package with a high capacity can be effectively improved.

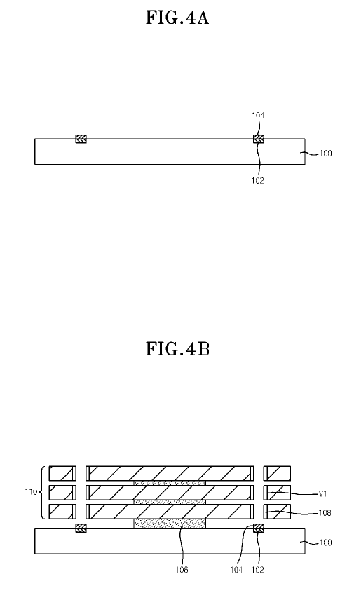

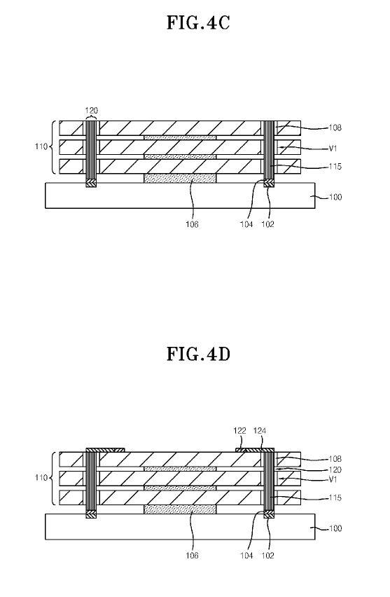

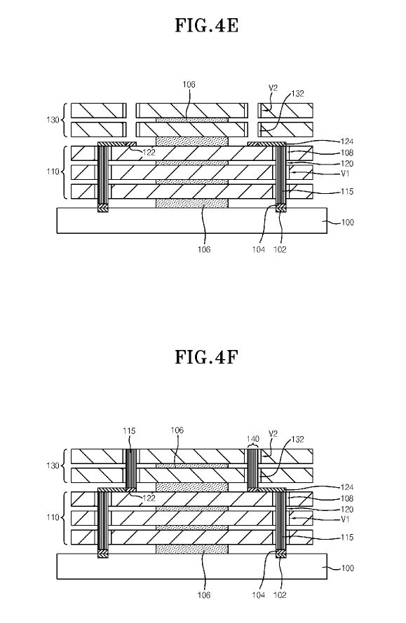

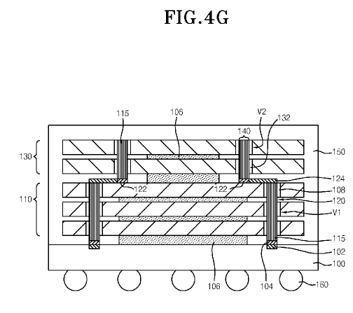

FIGS. 4A through 4G are cross-sectional views illustrating a method for manufacturing a semiconductor package in accordance with an embodiment of the present invention.

Referring to FIG. 4A, a substrate 100, having the first surface on which bond fingers 102 are formed and the second surface which faces away from the first surface and on which ball lands (not shown) are formed, is prepared. A catalytic metal layer 104 is formed on the bond fingers 102. The catalytic metal layer 104 is formed from one or more material such as, for example, Co, Mo, or Fe.

Although not shown in a drawing, the bond fingers 102 may be used without the catalytic metal layer 104 being formed. Accordingly, the bond fingers 102 may be formed from material such as, for example, Co, Mo, or Fe.

Referring to FIG. 4B, at least two semiconductor chips 110, each having via holes V1, are stacked on the first surface of the substrate 100 using, for example, adhesives 106. Before stacking the semiconductor chips 110, an insulation layer 108 is formed on inner surfaces of the via holes V1. The semiconductor chips 110 are stacked in such a manner that the via holes V1 are aligned vertically with respect to the first surface of the substrate 100 so as to expose the bond fingers 102 or the catalytic metal layer 104 of the substrate 100.

Referring to FIG. 4C, carbon nanotubes 115 are grown from the exposed bond fingers 102 or catalytic metal layer 104. As a consequence, through electrodes 120, which comprise the carbon nanotubes 115 and are electrically connected with the exposed bond fingers 102 or catalytic metal layer 104 and the semiconductor chips 110, are formed in the via holes V1.

The carbon nanotubes 115 are grown, for example, through PECVD (plasma enhanced chemical vapor deposition). The PECVD is conducted using plasma which is produced by a carbon-containing gas. The carbon-containing gas may be gas comprising, for example, one or more of C₂H₂, CH₄, C₂H₄, C₂H₆, and CO.

The carbon nanotubes 115 are grown vertically with respect to the first surface of the substrate 100 from the exposed bond fingers 102 or catalytic metal layer 104. As a consequence, the carbon nanotubes 115 are electrically connected with the exposed bond fingers 102 or catalytic metal layer 104. Accordingly, the semiconductor chips 110 are electrically connected with one another and the substrate 100 via the through electrodes 120.

Referring to FIG. 4D, an additional catalytic metal layer 122 is formed on portions of the top surface of the uppermost semiconductor chip 110, for example, on portions of the top surface of the uppermost semiconductor chip 110 which are adjacent to the through electrodes 120. The additional catalytic metal layer 122 may be formed of one or more material such as, for example, Co, Mo, or Fe.

The additional catalytic metal layer 122 is formed in such a way as to be electrically connected with the through electrodes 120 by means of redistribution lines 124 which are formed on the top surface of the uppermost semiconductor chip 110. The additional catalytic metal layer 122 and the redistribution lines 124 may be simultaneously formed. Alternatively, any one part of the additional catalytic metal layer 122 and the redistribution lines 124 may be formed first and the other part may be formed later.

Referring to FIG. 4E, at least two additional semiconductor chips 130, each having additional via holes V2, are stacked on the top surface of the uppermost semiconductor chip 110 using, for example, adhesives 106. Before stacking the additional semiconductor chips 130, an additional insulation layer 132 is formed on inner surfaces of the additional via holes V2.

The additional semiconductor chips 130 are stacked in such a manner that the additional via holes V2 are aligned vertically with respect to the top surface of the uppermost semiconductor chip 110 so as to expose the additional catalytic metal layer 122 formed on the uppermost semiconductor chip 110.

Referring to FIG. 4F, carbon nanotubes 115 are grown from the exposed additional catalytic metal layer 122. As a consequence, additional through electrodes 140, which comprise the carbon nanotubes 115 and are electrically connected with the exposed additional catalytic metal layer 122 and the additional semiconductor chips 130, are formed in the additional via holes V2.

The carbon nanotubes 115 are grown, for example, through PECVD (plasma enhanced chemical vapor deposition). The PECVD is conducted using plasma which is produced by, for example, a carbon-containing gas. The carbon-containing gas may be gas comprising, for example, one or more of C₂H₂, CH₄, C₂H₄, C₂H₆, and CO.

The carbon nanotubes 115 are grown vertically with respect to the top surface of the uppermost semiconductor chip 110 from the exposed additional catalytic metal layer 122. As a result, the carbon nanotubes 115 are electrically connected with the exposed additional catalytic metal layer 122, and the semiconductor chips 110 and the additional semiconductor chips 130 are electrically connected with each other by means of the additional through electrodes 140 comprising the carbon nanotubes 115.

Referring to FIG. 4G, An encapsulation member 150 is formed on the first surface of the substrate 100 on which the semiconductor chips 110 and the additional semiconductor chips 130 are stacked and the through electrodes 120 and the additional through electrodes 140 comprising the carbon nanotubes 115 are formed, in such a way as to seal the first surface of the substrate 100. External connection terminals 160 are formed on the ball lands (not shown), which are formed on the second surface of the substrate 100 facing away from the first surface.

Thereafter, while not shown in a drawing, by sequentially performing a series of subsequent processes as needed, the manufacture of a semiconductor package in accordance with an embodiment of the present invention may be completed.

In an embodiment of the present invention, through electrodes and additional through electrodes comprising carbon nanotubes, which have excellent electrical conductivity and mechanical properties, are formed to electrically connect semiconductor chips with additional semiconductor chips and the substrate. Accordingly, good electrical connections may be made between the semiconductor chips, the additional semiconductor chips, and the substrate. Accordingly, an embodiment of the present invention may improve the electrical characteristics and the reliability of a semiconductor package.

Further, in an embodiment of the present invention, as the carbon nanotubes are grown to pass through respective via holes of the semiconductor chips when the plurality of semiconductor chips are stacked on the first surface of the substrate, the carbon nanotubes can electrically connect the plurality of semiconductor chips in a single process.

As a consequence, in an embodiment of the present invention, it is not necessary to form connection members for connecting the through electrodes of the semiconductor chips. Thus, in an embodiment of the present invention, because the electrical connections between the through electrodes of the semiconductor chips are stabilized, the electrical characteristics and the reliability of the semiconductor package can be effectively improved.

In addition, in an embodiment of the present invention, the additional semiconductor chips are stacked on the semiconductor chips which are electrically connected by the through electrodes, and the additional through electrodes are formed to electrically connect the additional semiconductor chips with one another, with the semiconductor chips, and with the substrate. Hence, the electrical connections between the semiconductor chips, the additional semiconductor chips, and the substrate can be stably formed.

Accordingly, in an embodiment of the present invention, even when a number of semiconductor chips and a number of additional semiconductor chips are stacked on a substrate, stable electrical connections between the semiconductor chips, the additional semiconductor chips, and the substrate can be formed. Accordingly, the electrical characteristics and the reliability of the semiconductor package with high capacity can be effectively improved.

It was illustrated and explained in an embodiment of the present invention that the additional through electrodes for electrically connecting the additional semiconductor chips with the semiconductor chips are formed by forming an additional catalytic metal layer on the top surface of an uppermost semiconductor chip, and then growing carbon nanotubes from the additional catalytic metal layer. However, other embodiments of the present invention may form the additional through electrodes for electrically connecting the additional semiconductor chips with the semiconductor chips by growing carbon nanotubes without using the additional catalytic metal layer.

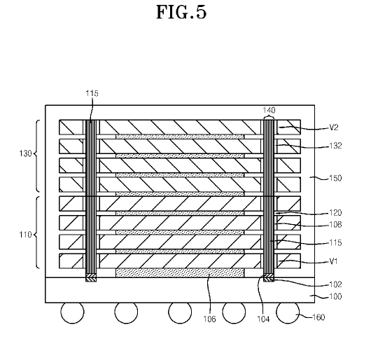

FIG. 5 is a cross-sectional view illustrating a semiconductor package in accordance with an embodiment of the present invention.

Referring to FIG. 5, bond fingers 102 are formed on the first surface of the substrate 100, and the catalytic metal layer 104 is formed on the bond fingers 102. The catalytic metal layer 104 may be formed of one or more material such as, for example, Co, Mo, or Fe.

Although not shown in a drawing, the bond fingers 102 may be used without the catalytic metal layer 104 being formed. Accordingly, the bond fingers 102 may be formed from material such as, for example, Co, Mo, or Fe.

At least two semiconductor chips 110 may be stacked on the first surface of the substrate 100, and adhesives 106 may be used to join the semiconductor chips 110 to each other and to join the bottommost semiconductor chip 110 to the substrate 100. Each of the semiconductor chips 110 has via holes V1, and an insulation layer 108 is formed on inner surfaces of the via holes V1. The semiconductor chips 110 are stacked in such a manner that the via holes V1 are aligned vertically with respect to the first surface of the substrate 100 so as to expose the bond fingers 102 or the catalytic metal layer 104 of the substrate 100.

Through electrodes 120, which comprise carbon nanotubes 115 and are electrically connected with the semiconductor chips 110, are formed in the via holes V1. The carbon nanotubes 115 are grown vertically with respect to the first surface of the substrate 100 from the exposed bond fingers 102 or catalytic metal layer 104. The carbon nanotubes 115 are electrically connected with the exposed bond fingers 102 or catalytic metal layer 104 such that the semiconductor chips 110 are electrically connected with one another and the substrate 100.

At least two additional semiconductor chips 130 are stacked over the uppermost semiconductor chip 110 using, for example, adhesives 106. Each of the additional semiconductor chips 130 has additional via holes V2. An insulation layer 132 is formed on inner surfaces of the additional via holes V2. The additional semiconductor chips 130 are stacked in such a manner that the additional via holes V2 are aligned vertically with respect to the top surface of the uppermost semiconductor chip 110 so as to expose the through electrodes 120.

Additional through electrodes 140, which comprise carbon nanotubes 115, are formed in the additional via holes V2. The carbon nanotubes 115 are grown vertically with respect to the top surface of the uppermost semiconductor chip 110 from the exposed through electrodes 120. The carbon nanotubes 115 are electrically connected with the exposed through electrodes 120 such that the additional semiconductor chips 130 are electrically connected with one another and the semiconductor chips 110.

An encapsulation member 150 is formed on the first surface of the substrate 100 on which the semiconductor chips 110 and the additional semiconductor chips 130 are stacked and the through electrodes 120 and the additional through electrodes 140 comprising the carbon nanotubes 115 are formed, in such a way as to seal the first surface of the substrate 100. Ball lands (not shown) are formed on the second surface of the substrate 100 which faces away from the first surface, and external connection terminals 160 are formed on the ball lands.

In the semiconductor package in accordance with an embodiment of the present invention, the through electrodes 120 and the additional through electrodes 140, which electrically connect the additional semiconductor chips 130, the semiconductor chips 110, and the substrate 100 with one another, comprise the carbon nanotubes 115. Accordingly, in an embodiment of the present invention, a semiconductor package structure with improved electrical characteristics and reliability can be realized through excellent electrical conductivity and mechanical properties of the carbon nanotubes 115.

Also, in the semiconductor package in accordance with an embodiment of the present invention, since the carbon nanotubes 115 are grown to pass through the via holes V1 of the plurality of semiconductor chips 110 and the additional via holes V2 of the plurality of additional semiconductor chips 130, connection members for electrically connecting the through electrodes 120 of the semiconductor chips 110 and the additional through electrodes 140 of the additional semiconductor chips 130 are not necessary.

Accordingly, in an embodiment of the present invention, the electrical connections between the through electrodes 120 of the semiconductor chips 110 and the additional through electrodes 140 of the additional semiconductor chips 130 are stabilized, whereby the electrical characteristics and the reliability of the semiconductor package can be effectively improved.

In addition, in the semiconductor package in accordance with an embodiment of the present invention, due to the fact that the additional semiconductor chips 130 are stacked on the semiconductor chips 110 and the carbon nanotubes 115 are additionally grown to electrically connect the additional semiconductor chips 130 with the semiconductor chips 110, the electrical connections between the semiconductor chips 110 and the additional semiconductor chips 130 can be stably implemented.

Therefore, in an embodiment of the present invention, even when an increased number of the semiconductor chips 110 and the additional semiconductor chips 130 are stacked on the substrate 100, stable electrical connections of the semiconductor chips 110 and the additional semiconductor chips 130 are enabled, and through this, the electrical characteristics and the reliability of a semiconductor package with a high capacity can be effectively improved.

In particular, in the semiconductor package in accordance with an embodiment of the present invention, since the respective additional via holes of the additional semiconductor chips are aligned in such a way as to expose the through electrodes of the semiconductor chips, the carbon nanotubes can be additionally grown from the exposed through electrodes without forming an additional catalytic metal layer. Accordingly, in an embodiment of the present invention, stable electrical connections between the semiconductor chips 110 and the additional semiconductor chips 130 are enabled even without additionally conducting a process for forming the additional catalytic metal layer.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package comprising:
a substrate having a first surface over which bond fingers are formed;
at least two semiconductor chips stacked over the first surface of the substrate, each semiconductor chip having via holes, wherein the semiconductor chips are stacked such that the via holes expose the respective bond fingers of the substrate; and
through electrodes, formed in the via holes with carbon nanotubes grown from the exposed bond fingers of the substrate, electrically connected with the semiconductor chips.

2. The semiconductor package according to claim 1, wherein the bond fingers comprises at least one of Co, Mo, and Fe.

3. The semiconductor package according to claim 1, further comprising:
a catalytic metal layer formed over the bond fingers.

4. The semiconductor package according to claim 3, wherein the catalytic metal layer comprises at least one of Co, Mo, and Fe.

5. The semiconductor package according to claim 1, further comprising:
an insulation layer formed on inner surfaces of the via holes.

6. The semiconductor package according to claim 1, further comprising:
adhesive interposed between a lowermost semiconductor chip and the first surface of the substrate and between the semiconductor chips.

7. The semiconductor package according to claim 1, further comprising:
an additional catalytic metal layer formed over an uppermost semiconductor chip;
at least two additional semiconductor chips stacked over the uppermost semiconductor chip, each semiconductor chip having additional via holes, wherein the additional semiconductor chips are stacked such that the additional via holes expose the respective additional catalytic metal layer; and
additional through electrodes, formed in the additional via holes with carbon nanotubes grown from the exposed additional catalytic metal layer, electrically connected with the additional semiconductor chips.

8. The semiconductor package according to claim 7, further comprising:
redistribution lines formed over the uppermost semiconductor chip to electrically connect the through electrodes of the uppermost semiconductor chip with the additional catalytic metal layer.

9. A method for manufacturing a semiconductor package, comprising the acts of:
stacking at least two semiconductor chips, each semiconductor chip having via holes, over a first surface of a substrate over which bond fingers are formed, such that the via holes expose the respective bond fingers of the substrate; and
forming through electrodes by growing carbon nanotubes, in the via holes, from the exposed bond fingers of the substrate, wherein the through electrodes are electrically connected with the semiconductor chips.

10. The method according to claim 9, wherein the bond fingers comprises at least one of Co, Mo, and Fe.

11. The method according to claim 9, wherein, before stacking the semiconductor chips, the method further comprises:
forming a catalytic metal layer over the bond fingers of the substrate.

12. The method according to claim 11, wherein the catalytic metal layer comprises at least one of Co, Mo, and Fe.

13. The method according to claim 9, wherein, before stacking the semiconductor chips, the method further comprises:
forming an insulation layer on inner surfaces of the via holes.

14. The method according to claim 9, comprising applying adhesive between the first surface of the substrate and the lowermost semiconductor chip, and between adjacent chips.

15. The method according to claim 9, wherein growing the carbon nanotubes is implemented through PECVD.

16. The method according to claim 15, wherein the PECVD is conducted using plasma which is produced by a carbon-containing gas.

17. The method according to claim 16, wherein the carbon-containing gas comprises at least one of C₂H₂, CH₄, C₂H₄, C₂H₆, and CO.

18. The method according to claim 9, wherein, after forming the through electrodes, the method further comprises:
forming an additional catalytic metal layer over an uppermost semiconductor chip;
stacking at least two additional semiconductor chips, each additional semiconductor chip having additional via holes, over the uppermost semiconductor chip such that the additional via holes expose the respective additional catalytic metal layer; and
forming additional through electrodes, by growing in the additional via holes carbon nanotubes from the exposed additional catalytic metal layer, electrically connected with the additional semiconductor chips.

19. The method according to claim 18, wherein, after forming the through electrodes and before forming the additional catalytic metal layer on the uppermost semiconductor chip, the method further comprises:
forming redistribution lines on the uppermost semiconductor chip in such a way as to enable electrically connecting the through electrodes of the uppermost semiconductor chip with the additional catalytic metal layer when the additional catalytic metal layer is formed.

20. The method according to claim 9, wherein, after forming the through electrodes, the method further comprises:
stacking at least two additional semiconductor chips, each additional semiconductor chip having additional via holes, over the uppermost semiconductor chip such that the additional via holes expose the respective through electrodes; and
forming additional through electrodes, by growing in the additional via holes carbon nanotubes from the exposed through electrodes, electrically connected with the additional semiconductor chips.
